(19) United States
(12) Patent Application Publication
(10) Pub. No.: US 2010/0321902 A1
(43) Pub. Date: Dec. 23, 2010

(54) CONNECTION STRUCTURE AND INFORMATION PROCESSING APPARATUS

(76) Inventors: Ichiro Hatakeyama, Tokyo (JP); Shigeyuki Yanagimachi, Tokyo (JP); Youichi Hidaka, Tokyo (JP); Ichiro Ogura, Tokyo (JP)

Correspondence Address: Mr. Jackson Chen, 6535 N. STATE HWY 161, IRVING, TX, 75039, US

(21) Appl. No.: 12/526,335

(22) PCT Filed: Nov. 26, 2007
(86) PCT No.: PCT/JP2007/072729

§ 371 Date: Aug. 7, 2009

(30) Foreign Application Priority Data
Mar. 9, 2007 (JP) 2007-060407

(51) Int. Cl. H05K 5/00

(52) U.S. Cl. 361/752

(57) ABSTRACT

A connection structure includes housing (10) having insertion/removal openings (11a, 12a) into which and from which a plurality of CPU cards (6), in which electronic parts are mounted on a circuit board, and switch cards (7) are inserted and removed, back plane (13) to which cards (6, 7) are electrically connected, and optical circuit board (14) that is optically connected to optical connectors (16) which are arranged on cards (6, 7) so as to be exposed to the outside of housing (10) from insertion/removal openings (11a, 12a) with cards (6, 7) connected to back plane (13).

### TECHNICAL FIELD

The present invention relates to a connection structure and an information processing apparatus for optically connecting function cards requiring high-capacity data processing and transmission.

### BACKGROUND ART

In recent years, performance necessary for an information processing apparatus such as computer has been remarkably increased. For example, in a computer system, the performance of a CPU (Central Processing Unit) thereof is rapidly improving the amount of calculation that can be performed has also increased by leaps and bounds. As an example of an information processing apparatus related to the invention, a so-called blade server is known in which one or more CPU cards, each formed by mounting a CPU on a circuit board, are mounted in a housing and the CPU cards are used for a linkage processing. The linkage processing between the CPU cards is executed by the communication through switch cards provided to the housing, by using an external interface (Ethernet etc.) mounted to the CPU card.

A general structure of a blade server related to the invention is shown in FIG. 1. As shown in FIG. 1, a front side of housing 110 is provided with CPU card slots 111 to which CPU cards 106 are mounted and switch card slots 112 to which switch cards 107 are mounted. The blade server is structured in such a way that switch cards 7 are mounted from the front side of housing 110, which is a direction the same as CPU cards 106. For the blade server, in order to reduce a maximum delay between CPU cards 106 and switch cards 107, which have an influence on linkage processing, it is generally adopted that switch cards 107 are arranged on a center of the front side positioned between respective CPU cards 106.

Recently, as performance of the CPU is enhanced, data transmission capacity is increased. As a result, even the Ethernet that has communication speed of 10 Gbps is used, so that the structure shown in FIG. 1 causes some problems. Generally, for physical transmission of an Ethernet communication of 10 Gbps, an electric interface of 2.5 Gbps×4 lanes referred to as XAUI (10 Gbit Attachment Unit Interface) is used. The electric interface has the transmission band of 2.5 Gbps per lane, so that the transmission distance is reduced, as compared to the slow electric signal (typically, for 2.5 Gbps, several centimeters are reduced). Hence, a design is required for suppressing the performance degradation of the linkage processing and for shortening the distance between CPU cards 106 and switch cards 107 (distributing length) as much as possible.

FIGS. 2A and 2B show a structure corresponding to high speed data transmission between CPU cards 106 and switch cards 107. As shown in FIGS. 2A and 2B, in the structure, CPU cards 106 are arranged to be attached and detached to and from the front side of housing 110 and switch cards 107 are arranged to be attached and detached to and from a backside of housing 110. Additionally, in the structure, in order to shorten a distributing length to switch cards 107 from respective CPU cards 106, a thickness direction of a circuit board of switch card 107 is arranged to be perpendicular to a thickness direction of a circuit board of CPU card 106. In other words, switch card slots 112 of switch cards 107 are arranged so that length directions of the insertion/removal openings thereof are perpendicular to those of insertion/removal openings of CPU card slots 111 of CPU cards 106.

Then, for the structure shown in FIGS. 2A and 2B, structures of each function card and a back plane (interface board) provided to housing 110 will be described. CPU card 106 and switch card 107 are respectively provided with an electric connector for data transmission (not shown), an electric connector for card control signal transmission (not shown), a power supply connector (not shown) and the like. In addition, as shown in FIGS. 3A and 3B, housing 110 is provided with back plane 113 that transmits data and a card control signal and that supplies power. Back plane 113 is also provided with electric connectors 131 for data transmission, electric connectors 132 for card control signal transmission, power supply connectors 133 and the like to be electrically connected to the respective electric connectors of CPU cards 106 and switch cards 107.

However, in the structures as shown in FIGS. 2A, 2B, 3A and 3B, back plane 113 is filled with respective electric connectors 131, 132, 133. Due to this, ventilation holes 134 of back plane 113 are so small, so that the flow of cooling air is impeded in housing 110. As a result, it is difficult to mount a high performance CPU having a relatively large heating value on CPU card 106 and to improve the performance of information processing of the whole system of the blade server.

Regarding this, a Japanese Patent Application Laid-Open No. 2003-121697 discloses a back plane in which a distributing length is not limited as compared to the electric transmission system, an optical transmission system capable of high speed and high capacity data transmission is used and electric and optical connections are mixed. FIG. 4 shows a structure of a back plane for a case where a back plane having electric and optical connections mixed is used for data transmission. As shown in FIG. 4, in back plane 140, only for data transmission in which high speed data communication is performed, is optical connection by optical connector 141 used. However, for the card control signal transmission that uses a slow signal having communication speed of 100 Mbps class, electric transmission is used as in the prior art. In the structure of back plane 140, the arrangement limitation on switch cards 107 is relaxed. Hence, it is possible to arrange switch cards 107 as shown in FIG. 1 and to enlarge the size of ventilation hole 134 as compared to the structure shown in FIGS. 2A and 2B.

### DISCLOSURE OF THE INVENTION

However, the above structure has the following problems.

First, in the information processing apparatus related to the invention, in which the CPU cards and the switch cards connecting the CPU cards are mounted and in which communication between the CPU cards and the switch cards is performed by the optical transmission, it is difficult to enhance the performance of the information processing apparatus.

The reason is as follows: although it is possible to make the size of the ventilation hole larger in the back plane, as compared to the structure of the electric transmission, an area of the back plane is still large. Due to this, the flow of cooling air is impeded in the housing by the back plane, so that it is difficult to mount a high performance LSI having a relatively large heating value as a function card.

Second, in the information processing apparatus related to the invention, in which the CPU cards and the switch cards connecting the CPU cards are mounted and in which communication between the CPU cards and the switch cards is performed by the optical transmission, it is difficult to perform the maintenance of the back plane having electric and optical connections mixed during the operation thereof. Further, in case of performing maintenance of the CPU cards, stopping the entire system of the information processing apparatus, is required, and thus so that the maintenance operation is troublesome.

The reason is as follows: the back plane having electric and optical connections mixed is generally arranged on a location at about 30 cm˜50 cm from the front side of the housing, which has the insertion/removal openings of the card slots arranged thereon, toward the backside of the housing. In addition, the interval of each CPU card has a relatively small pitch of about 20 mm. Due to this, in the information processing apparatus related to the invention, when there occurs a problem during the operation, it is difficult to remove any CPU card having the problem from the card slot and to clean the optical connector of the corresponding CPU card, which is arranged on the back plane.

An object of the invention is to provide a connection structure and an information processing apparatus enabling ventilation in a housing to be improved and the performance of information processing to be enhanced and capable of improving an operation ability when performing maintenance of an optical connector.

In order to achieve the above object, a connection structure related to the invention comprises a housing having a plurality of insertion/removal openings to and from which a plurality of function cards having electronic parts mounted on a circuit board are inserted and removed; an interface board to which each of the function cards is electrically connected; and an optical circuit board that is optically connected to optical connectors which are arranged on each function card so as to face the outside of the housing from the insertion/removal openings, with each of the function cards being electrically connected to the interface board.

According to the connection structure as described above, there are provided the interface card electrically connected to the respective function cards and the optical circuit board optically connected to the optical connectors of the respective function cards, so that an occupying area of the connectors to connect to the respective function cards is smaller on the interface board. Thus, it is possible to secure a relatively larger air passage for cooling in the housing. Due to this, it is possible to mount a high performance LSI (integrated circuit) having a relatively large heating value on the function card, so that it is possible to improve the performance of information processing. In addition, according to the connection structure, the optical circuit board is provided independently of the interface board, and the optical circuit board is connected to the respective function cards through the optical connectors arranged on the respective function cards so as to face the outside of the housing from the insertion/removal openings, with the respective function cards being electrically connected to the interface board. Hence, it is possible to easily perform maintenance operation of the optical connector.

Furthermore, an information processing apparatus of the invention comprises the connection structure described above.

Meanwhile, in the invention, the function card means a board that comprises CPU cards having CPUs, which are electronic parts, mounted on a circuit board and switch cards having switching elements, which switch to a linkage processing which is executed by the respective CPUs, mounted on the circuit board, and electronic parts fetching various functions are mounted thereto. Additionally, in the invention, the interface board refers to a board that comprises a so-called back plane and has connectors electrically connected to the connectors of the function cards.

According to the invention, a following first effect is obtained: there is provided an optical circuit board optically connected to the optical connectors arranged on the respective function cards so as to face the outside of the housing from the insertion/removal openings with the respective function cards being electrically connected to the interface board, so that a relatively larger air passage for cooling can be secured. Due to this, it is possible to mount a high performance LSI (integrated circuit) having a relatively large heating value on the function card, so that the performance of information processing can be improved.

A second effect is as follows: only a function card that experience a problem can be removed from the insertion/removal opening and the optical connector of the corresponding function card can be easily cleaned. Hence, it is possible to smoothly perform the maintenance operation without stopping the entire information processing apparatus.

### BRIEF DESCRIPTION OF THE DRAWINGS

FIG. 1 is a schematic view showing a first configuration example of an information processing apparatus related to the invention.

FIG. 2A is a schematic view showing a front side of a housing in a second configuration example of an information processing apparatus related to the invention.

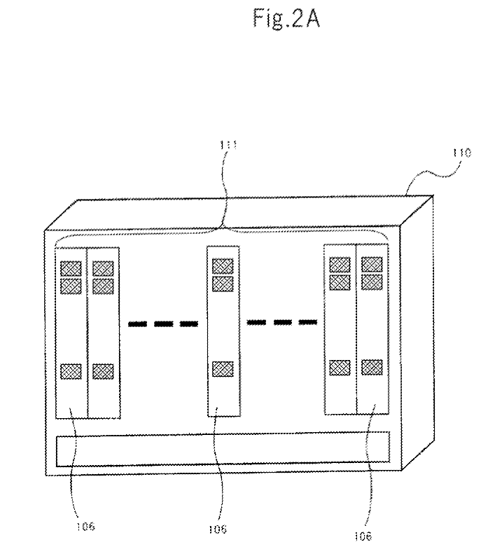

FIG. 2B is a schematic view showing a rear side of a housing in a second configuration example of an information processing apparatus related to the invention.

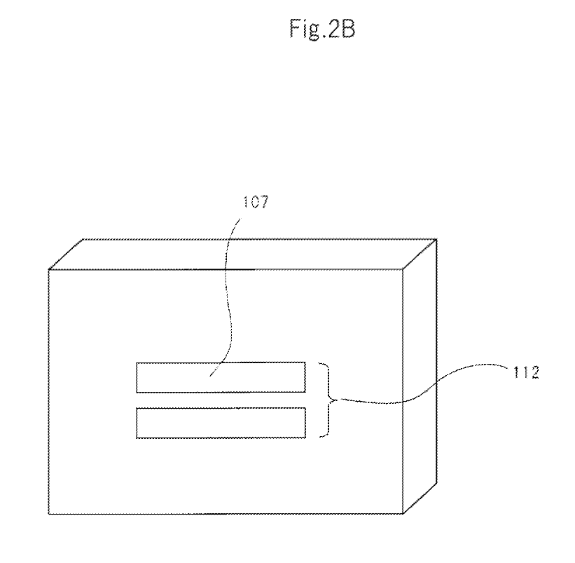

FIG. 3A is a front view showing a back plane provided to a second configuration example of an information processing apparatus related to the invention.

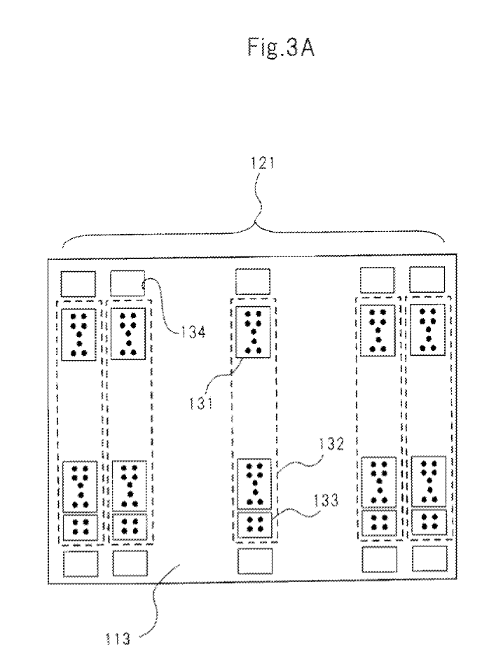

FIG. 3B is a rear view showing a back plane provided to a second configuration example of an information processing apparatus related to the invention.

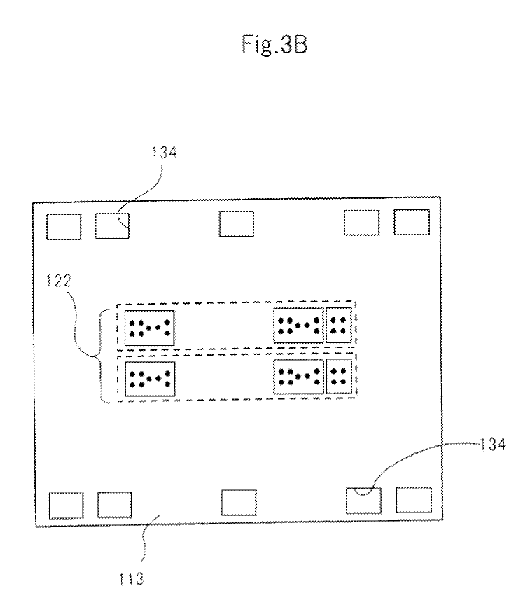

FIG. 4 is a schematic view showing a front side of a back plane provided to a third configuration example of an information processing apparatus related to the invention.

FIG. 5 is a schematic view showing an information processing apparatus of a first exemplary embodiment.

FIG. 6 is a schematic view showing a back plane provided to an information processing apparatus of a first exemplary embodiment.

FIG. 7 is a schematic view showing main parts of a second exemplary embodiment.

### BEST MODE FOR CARRYING OUT THE INVENTION

Hereinafter, exemplary embodiments of the invention will be specifically described.

The information processing apparatus of the exemplary embodiments is an information processing apparatus having card slots to which a variety of function cards, such as a CPU card having a CPU that is mounted on a circuit board as an electronic part, and a switch card having a switch element that is mounted on a circuit board as an electronic part, are detachably mounted. The information processing apparatus is applied to a so-called blade server and the like.

### First Exemplary Embodiment

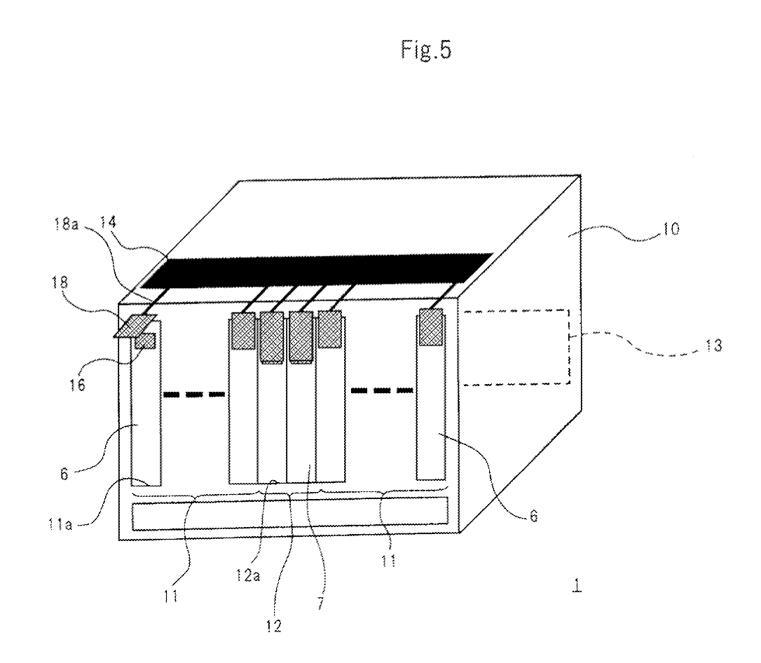

FIG. 5 is a schematic view showing an information processing apparatus according to a first exemplary embodiment. As shown in FIG. 5, information processing apparatus 1 of this exemplary embodiment comprises CPU card slots 11 to which CPU cards 6 are detachably mounted, switch card slots 12 to which switch cards 7 are detachably mounted, and housing 10 which includes each of insertion/removal openings 11a, 12a of each card slots 11, 12.

Further, information processing apparatus 1 has back plane 13, as an interface board, to which CPU cards 6 and switch cards 7 are electrically connected respectively, and has optical circuit board 14 to which CPU cards 6 and switch cards 7 are optically connected respectively.

Each of CPU cards 6 and switch cards 7 has an electric connector for a control signal and a power supply connector to which power is supplied from a power supply unit (not shown), which are not shown. In addition, each of CPU cards 6 and switch cards 7 has optical connector 16 for optical data transmission between CPU cards 6 and switch cards 7. Optical connectors 16 are arranged on end faces of CPU cards 6 and switch cards 7 so as to face the outside of housing 10 from insertion/removal openings 11a, 12a, i.e., to be exposed to the outside with CPU cards 6 and switch cards 7 mounted to card slots 11, 12 being electrically connected to back plane 13.

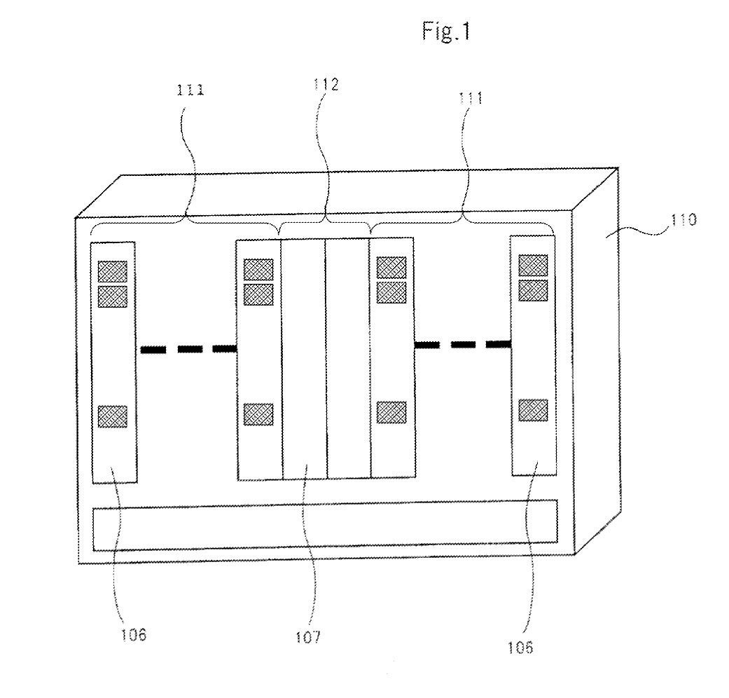

Insertion/removal openings 11a, 12a of CPU card slots 11 and switch card slots 12 are arranged on the front side of housing 10. In order to shorten a distributing length to each switch card 7 from each CPU cards 6, CPU card slots 11 are arranged on each side of the front side and switch card slots 12 are arranged on a center of the front side. In other words, this exemplary embodiment has a structure such that switch cards 7 are inserted and removed to and from housing 10 from a direction that is the same as CPU cards 6, as in the example related to the invention shown in FIG. 1.

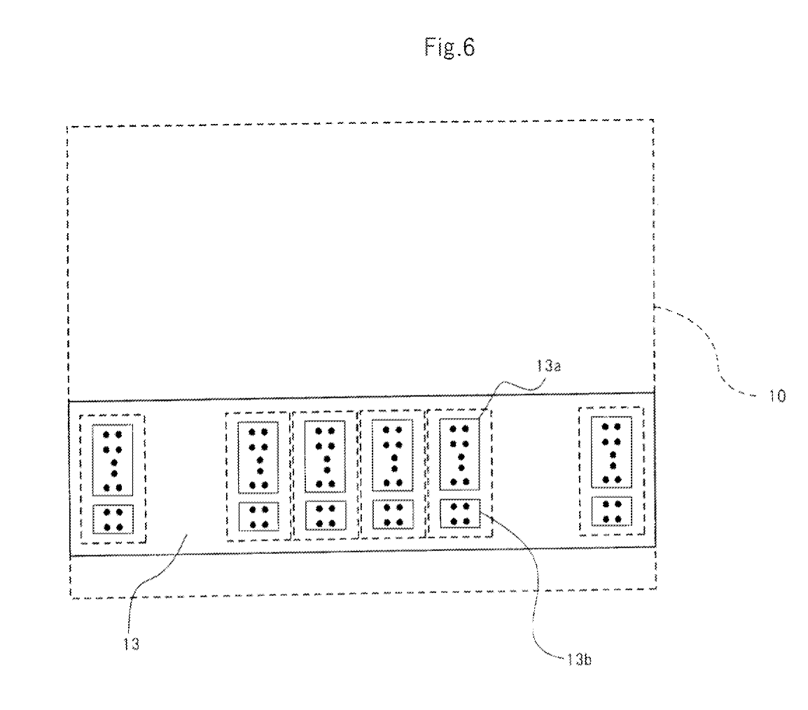

FIG. 6 shows a structure of back plane 13 provided to information processing apparatus 1 of the first exemplary embodiment. As shown in FIG. 6, back plane 13 has electric connectors 13a for a control signal to which the electric connectors of CPU cards 6 and switch cards 7 are connected, and has power supply connectors 13b to which the power supply connectors of CPU cards 6 and switch cards 7 are connected.

As shown in FIG. 5, optical circuit board 14 is arranged on an upper side of housing 10 near to the front side of housing 10. Optical circuit board 14 has a plurality of optical connectors 18 that are optically connected to respective optical connectors 16 of CPU cards 6 and switch cards 7, and has a circuit board to which respective optical connectors 18 are optically connected through flexible connection lines 18a.

Optical connectors 18 of optical circuit board 14 are respectively connected to optical connectors 16 of CPU cards 6 and switch cards 7 mounted to card slots 11, 12, so that the optical data transmission is performed between CPU cards 6 and switch cards 7.

In the meantime, optical circuit board 14 is not limited to the structure that it is arranged on the upper side of housing 10. In other words, the optical circuit board may be arranged on another position of housing 10 as long as it is separately arranged from back plane 13 which is arranged on the backside of housing 10.

According to this exemplary embodiment, because optical connectors 18 for optically connecting CPU cards 6 and switch cards 7, are not arranged on back plane 13, it is possible to reduce an area of back plane 13. Accordingly, it is possible to secure an air passage for cooling that has a relatively large area, which is to cool electric parts of CPU cards 6 and the like, around back plane 13 in housing 10.

According to the above structure, when operating information processing apparatus 1, it is possible to remove only CPU card 6 or switch card 7, which have a problem, from card slots 11, 12 and it is possible to easily clean optical connectors 18 of function cards 6, 7 thereof. Hence, it is possible to smoothly perform a maintenance operation without stopping the entire system of information processing apparatus 1.

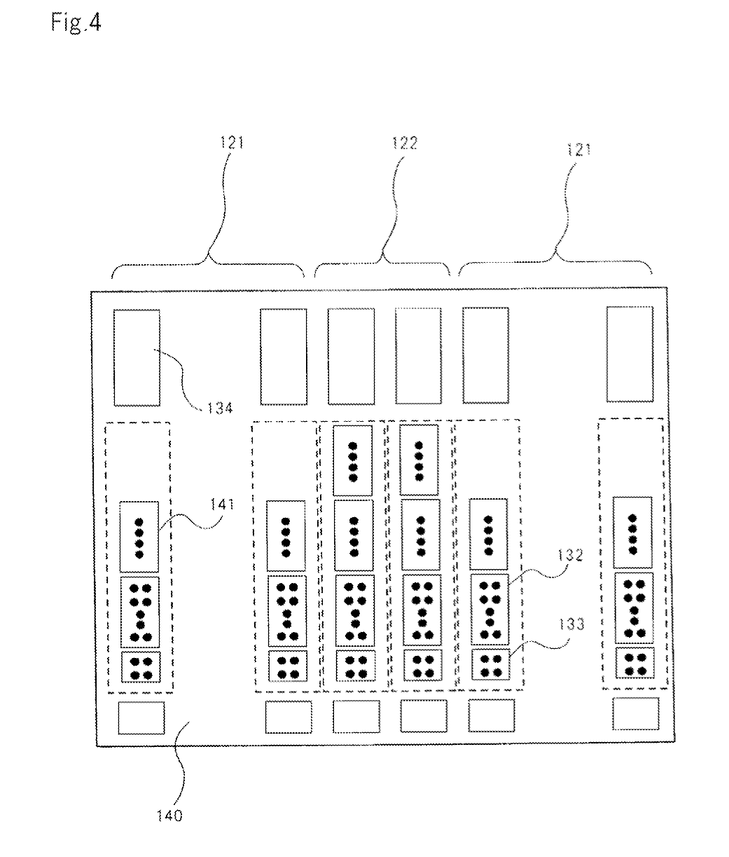

In addition, according to this exemplary embodiment, it is possible to downsize back plane 13 since there is no optical connector in back plane 13, as compared to the information processing apparatus related to the invention shown in FIG. 4, which comprises a back plane having electric and optical connections which are mixed. As a result, it is possible to secure a larger air passage for cooling CPU and the like in back plane 13. Accordingly, since the ventilation is enhanced in housing 10, it is possible to mount and use a high performance CPU having a relatively large heating value on CPU card 6, so that it is possible to enhance the processing performance of information processing apparatus 1.

Further, according to information processing apparatus 1 of this exemplary embodiment, because back plane 13 can be downsized, it is possible to downsize entire information processing apparatus 1.

Additionally, information processing apparatus 1 of this exemplary embodiment is very suitable for a connection structure in a housing in which function cards requiring a relatively high capacity of data processing and data transmission are optically connected.

### Second Exemplary Embodiment

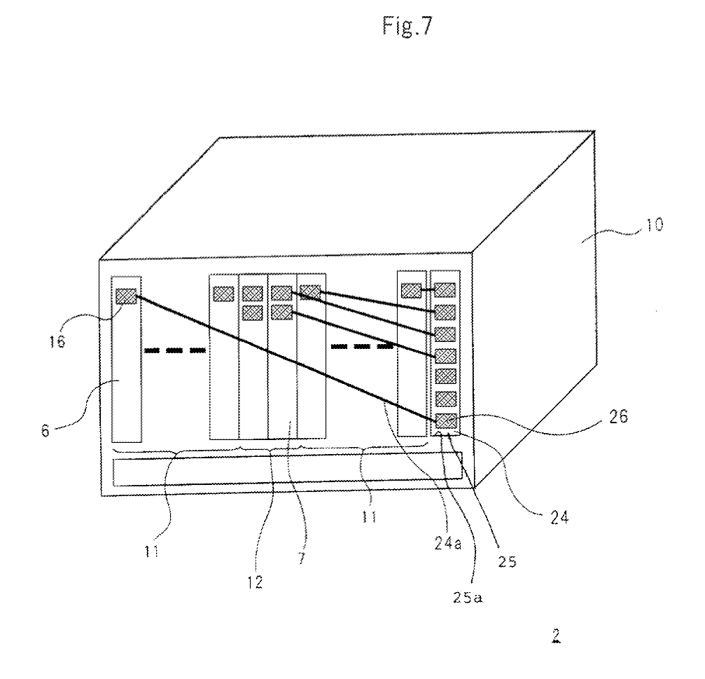

FIG. 7 is a schematic view showing a structure of main parts of an information processing apparatus of a second exemplary embodiment. The second exemplary embodiment has the structure of an optical circuit board different from that of the first exemplary embodiment shown in FIG. 5. In the second exemplary embodiment, an optical circuit board is comprised of an optical circuit card comprising one function card in which an optical connector is arranged on an end face of a front side of a housing. The optical circuit card is structured in such a way that it is mounted to a card slot arranged on the front side of the housing. Meanwhile, in the second exemplary embodiment, the members that are the same as those of the first exemplary embodiment are indicated by the same reference numerals and descriptions thereof will be omitted.

As shown in FIG. 7, information processing apparatus 2 of this exemplary embodiment comprises optical circuit card 24 to which CPU cards 6 and switch cards 7 are optically connected, and card slot 25 to which optical circuit card 24 is detachably mounted.

Optical circuit card 24 comprises a plurality of optical connectors 26 that are optically connected to respective optical connectors 16 of CPU cards 6 and switch cards 7, and comprises a circuit board to which optical connectors 26 are optically connected through flexible connection lines 26a. Optical connectors 16 are arranged on an end face of optical circuit card 24 so as to face the outside of housing 10 from insertion/removal opening 25a with optical circuit card 24 being mounted to card slot 25.

Card slot 25 is arranged on the front side of housing 10 and insertion/removal opening 25a into and from which optical circuit card 24 is inserted and removed is provided to the front side.

In this exemplary embodiment, optical circuit card 24 is mounted to card slot 25 and optical connectors 26 of optical circuit card 24 are respectively connected to optical connectors 16 of CPU cards 6 and switch cards 7 mounted to card slots 11, 12, so that the optical data transmission is performed between CPU cards 6 and switch cards 7.

Hence, according to this exemplary embodiment, it is possible to obtain the effects of enhancing ventilation in housing 10, the performance of information processing and the maintenance operation of optical connectors 16, 26, as in the first exemplary embodiment.

Meanwhile, in this exemplary embodiment, the optical connectors of the function card are arranged on the end face of the function card so as to be exposed to the outside of the housing from the insertion/removal openings, with the function card being mounted to the card slot. However, the optical connectors of the function card may be arranged on another position as long as the position faces the outside of the housing and the optical connectors can be easily connected to the position from the outside.

While the invention has been shown and described with reference to the exemplary embodiments thereof, the invention is not limited thereto. In other words, it will be understood by those skilled in the art that various changes in form and details may be made thereto without departing from the spirit and scope of the invention as defined by the appended claims.

This application claims the priority of Japanese Patent Application No. 2007-060407 filed on Mar. 9, 2007, the disclosures of which are incorporated herein by reference.

1. A connection structure comprising:
a housing having a plurality of insertion/removal openings to and from which a plurality of function cards having electronic parts mounted on a circuit board are inserted and removed;
an interface board to which each of the function cards is electrically connected; and
an optical circuit board that is optically connected to optical connectors which are arranged on each function card so as to face the outside of the housing from the insertion/removal openings, with each of the function cards being electrically connected to the interface board.

2. The connection structure according to claim 1, wherein each function card has an electric connector for a control signal, a power supply connector to which power is supplied, and the optical connector for optical data transmission between the function cards, and
wherein the interface board has electric connectors for a control signal to which the electric connectors of the respective function cards are connected, and power supply connectors to which the power supply connectors of the respective function cards are connected.

3. The connection structure according to claim 1, wherein the optical circuit board is provided to the housing.

4. The connection structure according to claim 3, wherein the optical circuit board is arranged on a front side of the housing to which the insertion/removal openings are arranged.

5. The connection structure according to claim 1, wherein the optical circuit board is an optical circuit card that is inserted and removed to and from the insertion/removal openings.

6. An information processing apparatus comprising the connection structure according to claim 1.
